(19) United States
(12) Patent Application Publication
(10) Pub. No.: US 2002/0131238 A1
(43) Pub. Date: Sep. 19, 2002

(54) Heat sink

(75) Inventors: Francis Edward Fisher, Swindon (GB); Russell Bowles, Swindon (GB)

Correspondence Address: Edward M. Weisz, Esq., Cohen, Pontani, Lieberman & Pavane, 551 Fifth Avenue, Suite 1210, New York, NY, 10176, US

(73) Assignee: Aavid Thermalloy LLC

(21) Appl. No.: 09/939,356

(22) Filed: Aug. 24, 2001

(30) Foreign Application Priority Data
Mar. 16, 2001 (GB) 0106547.3

(51) Int. Cl. H05K 7/20; H01B 7/42; F28F 7/00

(52) U.S. Cl. 361/719; 361/710; 174/15.2; 165/80.3

(57) ABSTRACT

A composite heat sink devise includes a heat sink body formed of aluminum, the body having a pair of coplanar surfaces, and a thermally conductive solderable element, for example of copper, mechanically fixed to each of the coplanar surfaces. Each of the solderable elements has a first surface which is contiguous with one of the coplanar surfaces, and a second surface which is soldered to a printed circuit board.

### BACKGROUND OF THE INVENTION

1. Field of the Invention

The invention relates to the cooling of electronic devices by use of a heat sink that is surface-mounted in sufficient proximity to the device to be cooled. In particular, the invention is concerned with heat sinks of the formed fin or shaped body of thermally conductive plate types.

2. Description of the Related Art

Heat sinks are required in electronic equipment such as system boards for computers, central processing units, memory devices, control devices, power amplifiers etc., because the electronic devices typically used therein generate heat in normal usage and moreover, have an optimal operational temperature range outside of which the operational capacity of the device(s) can be impaired due to thermal degradation or overload. Accordingly, it is essential to locate a thermal conducting element on such a device or juxtaposed thereto in sufficient proximity to conduct heat from the device and dissipate it into the ambient air by convection and radiation.

Even though an individual device such as a transistor or small integrated chip (i.c.) in isolation may be able to radiate heat generated during its normal operation, it will be recognized that with the increasing complexity of electronic products, coupled with a demand for compactness (small footprint), the heat density generated within a product can be very high. This problem can only become more demanding as the processing power of products increases.

In a typical usage, such as assembly of a mother board for a personal computer, there may be a large number of electronic devices connected in close proximity upon a printed circuit board (PCB) bearing copper connectors and solder paste areas. The more complex boards have to handle a considerable heat load and often the boards themselves include thermal conductors to take heat away from the devices and connecting circuitry. Such boards are often provided as laminates of insulator material and metal conductors with metal rods or plates traversing the laminates to conduct heat away from a surface bearing electronic devices to a remote surface and the arrangement is such as to attempt to dissipate heat throughout the board to avoid hot spots being created that could lead to overload of the board and potential failure of its electronic component devices. The industry would prefer to avoid complex constructions for the boards, and many heat-dissipating devices have been attached to such boards to conduct, convect and radiate heat out of the board.

Heat dissipating devices may be provided with solder tags for insertion into apertures (socket mounting) in a substrate (PCB), and are retained therein by soldering of such “through board attachments”. Such a heat-dissipating device will often be in direct contact with the electronic device to be protected and dissipates heat conducted from that device, and the board to which it is mounted. In other arrangements, the heat dissipating device is mounted above and partially surrounding the electronic device such that the heat dissipating device conducts heat therefrom via its attachment to the board, and dissipates that heat by convection and radiation into the ambient air. In some arrangements, the heat-dissipating device is fixed to the device by a thermally conductive slug using a solder paste.

More information on the known heat dissipation devices and their arrangement or PCBs and the like can be found by referring to earlier patents. Thus reference may be made to U.S. Pat. Nos. 6,085,833; 5,779,134; 5,771,966; 5,396,403; 5,339,519; 5,311,928; 5,172,301; 4,403,102; and 5,930,114 See also WO 99/18762; WO 97/43783; WO 96/36994; WO 96/36995; and EP 026 931,.

The heat dissipating devices, commonly referred to as “heat sinks”, are passive devices formed from a metal such as aluminum, copper, or metal alloys with good thermal conductivity characteristics, such as copper with tungsten.

Such heat sinks, in common with the electronic devices that they are intended to protect are generally soldered using a solder paste containing a lead tin alloy.

While aluminum is a good material for use in heat sinks, e.g. it is lighter and cheaper than copper or copper alloys, it is not readily soldered due to its oxide layer. Consequently, aluminum heat sinks are normally provided with solderable non-aluminum insertion tags for location within a socket in a substrate.

Interest in obtaining more compact electronic packages has brought about increased interest in surface mounting of devices. U.S. Pat. No. 5,779,134 describes one way of applying surface mount technology to heat sinks.

Currently, heat sinks adapted to be surface mounted are formed generally from copper coated with a solder receptive alloy, i.e. one containing tin to confer compatibility with the common Pb/Sn based solder compounds and pastes.

While these surface mounted heat sinks are currently commercially successful, the cost thereof, and poorer thermal dissipation performance when judged against a comparable size of heat sink constructed of blackened aluminum or an aluminum alloy leads to a desire to find an alternative heat sink.

U.S. Pat. No. 5,930,114 discloses a heat sink device including a mounting attachment of solderable material such as copper and a heat sink having extensions which are fixed to the mounting attachment by a locking mechanism which provides only limited thermal contact between the two parts.

### SUMMARY OF THE INVENTION

It is an object of the invention to provide an alternative heat sink capable of being surface mounted on a substrate using a common solder material.

This object is achieved by forming a heat sink body, especially from a sheet of thermally conductive metal, particularly aluminum or an alloy thereof, and preparing it for forming to provide heat dissipating fins and surface mounting lands, and providing at least one thermally conductive solderable element for each land. The order of steps for forming to achieve the desired profile, and attaching each thermally conductive solderable element to the respective land(s) by a mechanical fixing may vary dependent upon the manner of mechanical fixing chosen. Suitable heat sink bodies can also be formed by extrusion.

Suitable mechanical fixings include an interference fit achievable by part-shearing or semi-perforating a land surface to provide a spigot or the like keying formation, and providing a corresponding socket or keyway in at least one thermally conductive solderable element. The land is presented to the element to mate the corresponding parts and form an interference fit between the spigot and socket, the interference fit being made sufficiently secure for the intended surface mounting use of the heat sink by swaging for example. In those circumstances the attachment of the solderable element to the land is most conveniently achieved by swaging before the sheet is formed to its intended heat sink profile.

Another suitable form of mechanical fixing of the corresponding surfaces to be fixed together is riveting, especially the technique of “self-riveting” wherein, at predetermined points on one of such surfaces, a surface portion is displaced by a punch tool or the like. The displaced part extends into a corresponding depression or hole formed separately in the corresponding surface to which the one such surface is to be fastened.

Thus according to one aspect in a heat sink assembly consists essentially of aluminum with the assembly being of the type adapted to be attached to a PCB for the purposes of obviating or mitigating the risks of thermal overloads. The improvement resides in the thermally conductive solderable elements attached mechanically to the heat sink assembly to provide a means of surface mounting the heat sink assembly on the PCB by soldering.

Such a heat sink can be surface mounted on an appropriately prepared substrate such as a PCB, not an electronic device, and heat can be conducted to the heat sink via a thermally conductive seat, typically a copper pad applied to the substrate.

Thus according to an aspect of the invention, there is provided a heat sink body formed from a sheet or plate of thermally conductive metal, or alternatively by an extrusion process known per se to provide heat dissipating fins, and legs suitably arranged to provide a means of support for the body in its intended use. The legs are provided with lands for the purposes of surface mounting, and thermally conductive solderable elements are mounted and mechanically attached thereon so as to be contiguous with and sufficiently extensive across the lands to provide a suitable means for surface mounting of the heat sink body by a soldering technique.

Preferably the heat sink body is formed by folding, bending or the like actions upon a sheet of metal, optionally involving cutting and/or punching. In particular, the portions of the sheet intended to form lands of the heat sink body may be suitably prepared for receiving the solderable elements by being stamped or otherwise subjected to part-shearing or semi-perforation to cause projections to emerge from the plane of the sheet of metal.

The shape for the heat sink body may be relatively simple, involving a plurality of substantially parallel folds in alternate directions to provide a corrugated sheet where alternate folds provide potential land surfaces available for surface mounting use, with heat dissipating fins extending obliquely away from such land surfaces. In use, the land surfaces conduct heat from the surface mounting on the substrate via the solderable element(s) into the body for heat dissipation.

Generally, the heat sink body will be adapted to accommodate mounting thereof around a predetermined surface area to which an electronic device to be protected from heat overload is located. The mounting juxtaposes the heat sink with respect to the device to permit dissipation of heat generated therefrom through the heat sink body. One suitable shape provides support means in the form of legs or walls that in use are upstanding from the surface a upon which the heat sink is mounted, the legs or walls being spaced sufficiently to straddle the device to be protected, and being connected by a bridging heat sink body part which conveniently also acts as a heat dissipating surface e.g. a planar fin element. It will be understood that in use thermal conductivity through the heat sink body, together with convection currents in the air, and radiation of heat from the surfaces of the heat sink act to dissipate heat away from the device.

According to one embodiment of such a heat sink, the body is formed from a metal (either form sheet or by extrusion) to provide heat dissipating fins in substantially parallel planes, and support elements extending away from the planes to provide surface mounting lands remote from the major surface areas of said fins, and thermally conductive solderable surface mounting elements are aligned with and mechanically attached to the lands.

The preferred material is aluminum or an alloy thereof, because aluminum is strong, ductile and readily shaped, has desirable inherent thermal characteristics, is relatively abundant and correspondingly cheaper than other thermally suitable metals, and its thermal characteristics may be enhanced by coloring with pigments by anodizing or painting. Thus, the heat dissipating surfaces may be colored e.g. blackened, to provide a high performance heat transfer surface.

These properties of aluminum are widely recognized but aluminum has the drawback of being non-receptive to soldering. This problem is solved by the invention by providing a thermally conductive solderable element attached over the lands of the aluminum heat sink body.

Such an element is provided by applying a solder paste compatible coating over a thermally conductive carrier element. The thermally conductive solderable element may take the form of a thin sheet, which is adequately conformable to the land surfaces to which it has to be mechanically attached (as described elsewhere herein). Suitably the element comprises a light metal carrier sheet with a plating of a solder compatible metal e.g. tin or an alloy thereof so as to be compatible with solder paste as commonly used in the industry. The element may be prepared for the intended interference fit with the prepared lands of a heat sink body of this invention e.g. by boring, cutting, or punching of suitable sockets, either before or after the solder paste—compatible coating is applied.

The shape of the elements for providing the solderable thermal connection between the desired aluminum heat sink body and the substrate is one adapted to conform sufficiently with the lands of the support elements of the heat sink body as to permit satisfactory surface mounting. In order to facilitate or enhance the mechanical attachment of the contiguous surfaces of the heat sink body support elements with the solderable elements, the elements may be tagged or provided with upstanding portions to enable overlay of the tag or upstanding portion upon a surface of the support element and fastening thereof by use of a rivet or the like surface-penetrating fastener.

According to another aspect of the invention, the problem of attaching an aluminum heat sink body to a substrate such as a PCB by a surface mounting technique using solder paste or the like is solved by preparing the substrate for receiving such a heat sink body by soldering at least one solderable element at a predetermined location on or at a heat conductive region of the substrate where the heat sink is to be surface mounted, said solderable element being adapted to receive a heat sink body and retain same in the desired location by a mechanical fixing.

The respective solderable element(s) may be provided thereof upon a surface of the support element and fastening therebetween by use of a rivet or the like surface-penetrating fastener.

According to another aspect of the invention, a surface mounting arrangement for attaching a heat sink to a suitably prepared surface on a PCB, includes a clip formed from a resilient thermally conductive material to provide confronting surfaces and a common base therebetween, the base having a solder-compatible surface. One of the confronting surfaces is resiliently biased towards the other, but is sufficiently pliant to permit a part of a heat sink body to be inserted between the confronting surfaces, and the biased surface is formed to provide a detent adapted to cooperate with a corresponding recess in said part of a heat sink body. In this surface mounting arrangement, the clip provides a solderable element. In use the clip is oriented correctly to present the base for soldering upon the surface of the PCB to fix the clip in a generally upright position, thereby enabling a part of a suitable heat sink body to be forced home into the clip whereupon it is retained in position by inter-fitting of the detent with a recess provided for this purpose in the relevant part of the heat sink body. The resilience of the clip is sufficient to maintain the inter-fitting relationship unless the heat sink body is intentionally and forcibly removed by pulling. This aspect facilitates assembly of heat sinks upon the appropriately prepared PCB and also permits removal of the heat sink when required.

The heat sink body to be attached upon the solderable element has dependent supports having at least one edge, or one surface providing a contiguous contact with the solderable element to permit a thermal conductivity path to be present in the complete assembly.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

FIG. 1(a) is a perspective view of a heat sink adapted for surface mounting;

FIG. 1(b) is a part-sectional view of a part of the heat sink shown in FIG. 1, and illustrating schematically the structural parts for achieving a mechanical interfit in the assembly;

FIG. 2 illustrates schematically, in three stages, a typical “re-flow” process for attaching components to a prepared surface;

FIG. 3 shows a surface mounting arrangement suitable for use with a heat sink (not shown in complete form).

FIG. 4 shows an alternative surface mounting arrangement for an element of a heat sink body (not shown in complete form);

FIG. 5 shows a further alternative surface mounting arrangement for an edge-mounted element of a heat sink body (not shown in complete form);

FIG. 6 shows an alternative surface mounting arrangement relying upon a spring clip; and

FIG. 7 illustrates a heat sink body surface mounted in position upon solder paste pads.

### DETAILED DESCRIPTION OF THE PRESENTLY PREFERRED EMBODIMENTS

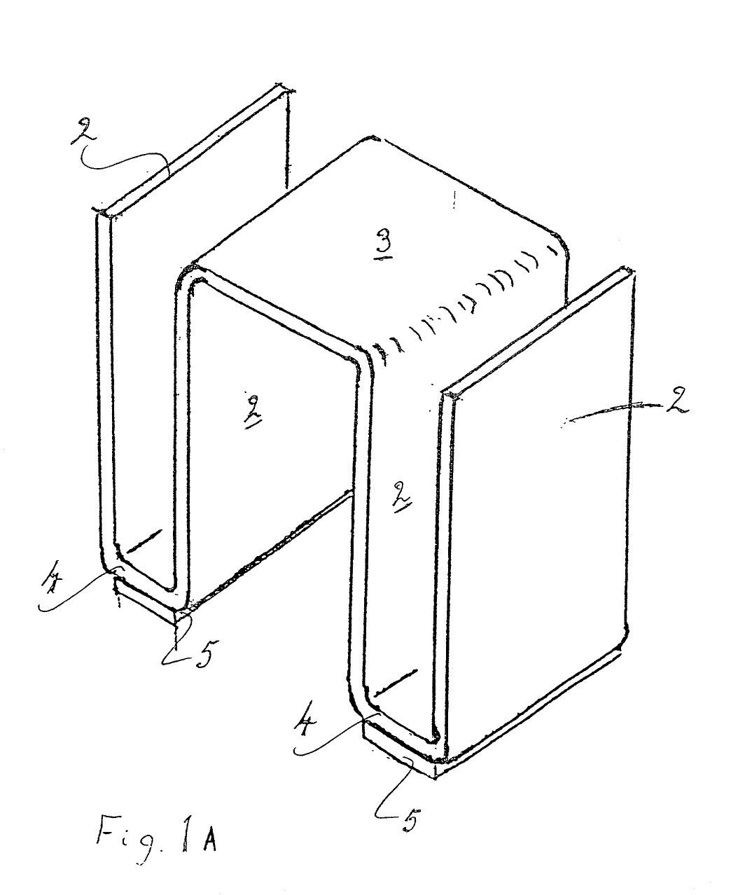

A surface mounted heat sink assembly according to one aspect of the present invention is illustrated in FIG. 1. An anodized blackened, aluminum sheet is formed to provide a finned heat sink 1 having freely extending heat dissipating fins 2 arranged on either side of a planar section 3 intended to be arranged in use over an electronic device (not shown) to be protected against heat overload. The heat sink 1 has surface mounting lands 4 at the base of the heat sink which are adapted for soldering to a substrate by a soldering technique known per se in the field, e.g. solder reflow methods, by the provision of thermally conductive solderable elements 5. These solderable elements 5 are contiguous with and extend over the surface of the lands 4, and are retained in position by a mechanical fixing (FIG. 1(b)). Such a mechanical fixing is achievable by partially shearing or semi-perforating the land to drive out a projection to provide a spigot 6 (FIG. 1b) that is inserted into a corresponding socket 7 formed in the solderable element 5, and that interference fit is enhanced by swaging the element 5 onto the land 4. It will be appreciated that the swaging operation is best carried out before the sheet is formed into the desired finned profile of the heat sink body shown in FIG. 1.

The heat sink is formed from a sheet of anodized blackened aluminum and the location of the intended fold lines and part shear or semi-perforation points are predetermined therein. The necessary part-shearing step is performed upon the sheet using known procedures, to provide the required spigots 6 within the area of a seating position for the solderable elements 5.

In other embodiments, not illustrated, the aluminum may be extruded to provide the desired profile. The aluminum can also be pigmented, colored or treated in other ways, e.g. painting, to provide or improve the desired surface properties. Equally, any desired color may be used to achieve a selected effect, so that it may be white for some applications.

Suitably prepared solderable elements 5 having a generally planar rectangular shape and sockets in the surface thereof for receiving the spigots are delivered to the required location, pressed into place, and swaged to secure same to the lands.

In use of the embodiment shown in FIG. 1, the heat sink is oriented to present the lands for surface mounting and on either side of a device to be protected against heat overload, such that the planar surface 3 is positioned over the device (not shown).

As is known in the field, the heat sink dissipates heat by a combination of conduction of heat by contact with hot surfaces e.g. the regions of contact between the lands 4 and the elements 5 in the surface mounting arrangement with the respective areas of substrate (not shown in FIG. 1), and by convection through ambient air currents, and radiation from the heat sink body.

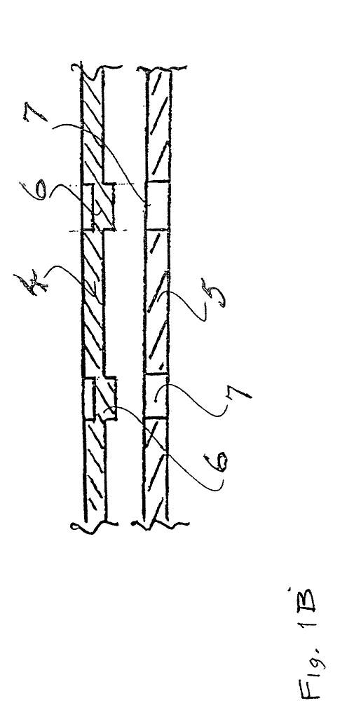

Accordingly, in normal use the heat sink is surface mounted upon a substrate such as a PCB, which is prepared by the usual masking techniques to present surface areas in predetermined positions for receiving electronic devices. Adjacent such positions solder paste is applied to thermally conductive surfaces e.g. copper pads, and the heat sink body is properly oriented and seated upon the solder paste, to present the solderable elements for soldering thereto. As illustrated schematically in FIG. 2, a known solder reflow technique is applied to surface mount the heat sink into position on the substrate.

In this process the solder is screen printed onto selected copper pads of a printed circuit board (PCB). The heat sink of the invention being properly positioned, heat is then applied to the assembly such that the solder melts (reflows) and bonds with the solderable elements 5 which upon cooling fixes the heat sink in place. This is achievable in an oven, e.g. an infra-red oven.

Other techniques such as wave-soldering are known in the art, but the re-flow technique is currently preferred.

Furthermore, in modifications according to the invention, other heat sink devices may be attached by variants in design of the solderable elements 5.

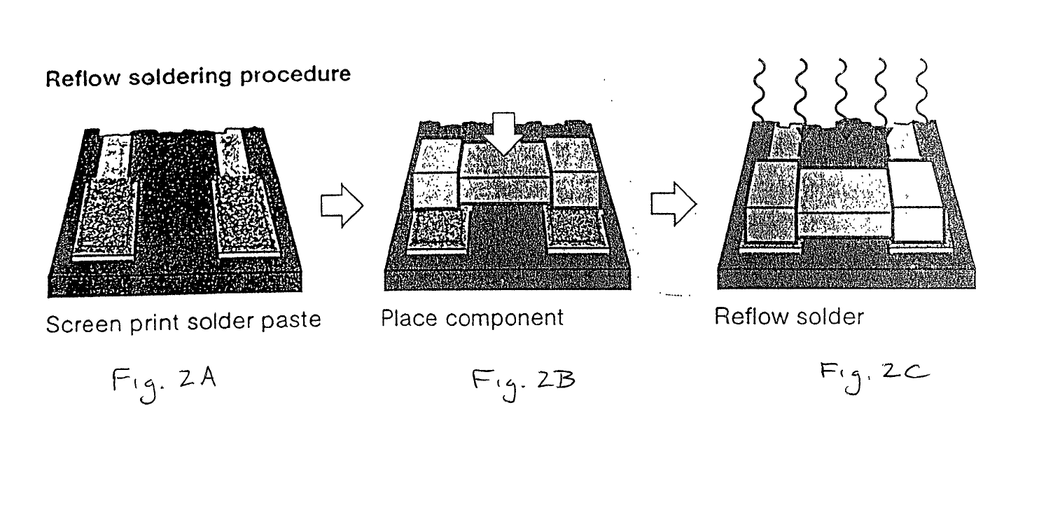

FIG. 3 shows an alternative design suitable for use with other heat sinks, wherein there is shown a finned heat sink mounting wall 31, and cooling fins 32, to which wall an L-shaped profile solderable element 35 is attached by a surface penetrating fastener indicated here as a “rivet” 33. The element is made of a light thermally conductive material having a coating of tin or tin alloy applied to the surfaces 34 intended for soldering to a substrate, and the heat sink is made of anodized/colored aluminum. The riveting technique, provides a positive reliable mechanical fixing of good strength and offers the ability to provide good thermal contact between the L-shaped profile element 35 and the heat sink wall 31, without compromising the surface mounting capability which is achievable by proper positioning on solder paste pads on the PCB and re-flow soldering as before.

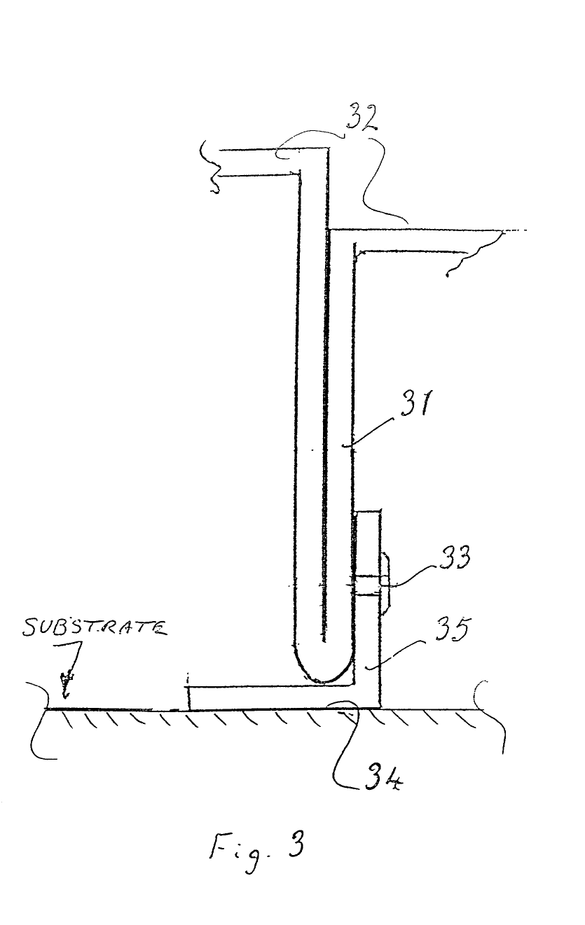

FIG. 4 shows a similar arrangement with a different type of heat sink body which presents simply a single fin 41 with a bottom edge 44 of low surface area, but the thermal conductivity is maintained by the contact between the overlying upstanding limb of the solderable element 45 and side wall surface area, that contact being maintained secure by surface penetrating fastener indicated here as a rivet 48.

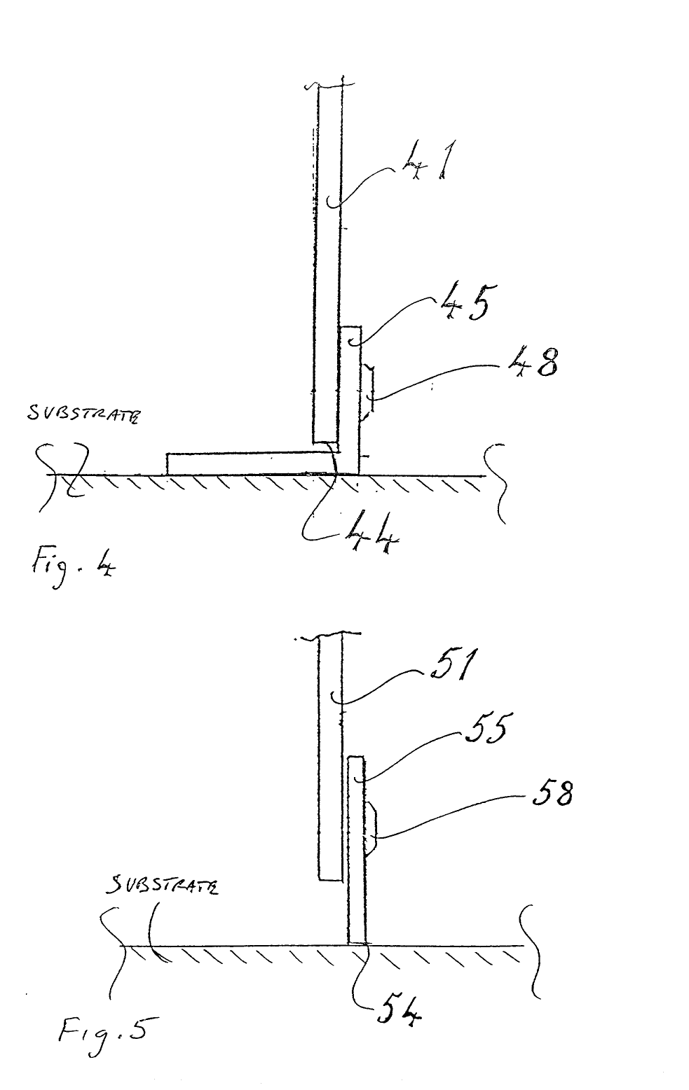

FIG. 5 shows a similar fin wall 51 of a heat sink with an edge (54) mounting solderable element 55 fastened to the wall using a surface penetrating fastener indicated here as a rivet 58. This would be suitable for applications where space is at a premium.

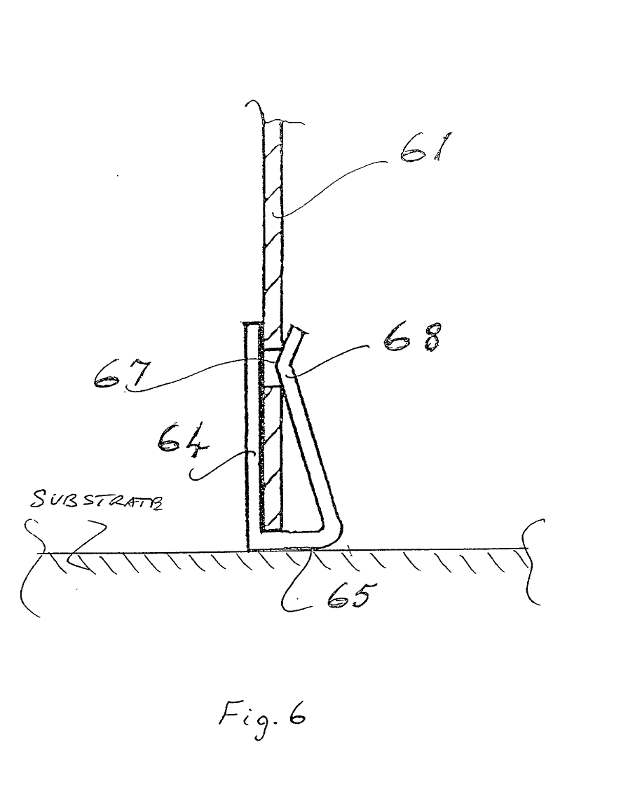

FIG. 6 shows a surface mounting arrangement for a fin 61 of a heat sink, wherein the fin is prepared for mounting by provision of a hole 67, and a retention clip 64 having a solder receptive base 65, is surface mounted on a substrate by soldering. The heat sink is subsequently pushed home into a seating position, and retained there by provision of a detent 68 which extends into the hole 67 to provide a simple but effective mechanical fixing.

In alternative variants of the invention, the PCB substrate is fully prepared for surface mounting of heat sinks in operational relationship to heat generating devices to be protected against thermal overload, by positioning solderable elements with upstanding limbs, especially L or, substantially V, or U-shaped profile elements, upon solderable thermally conductive seats on the substrate surface with solder paste present and to fix same by a reflow solder technique. This allows the heat sinks to be subsequently properly oriented, positioned and surface mounted mechanically into place without further soldering.

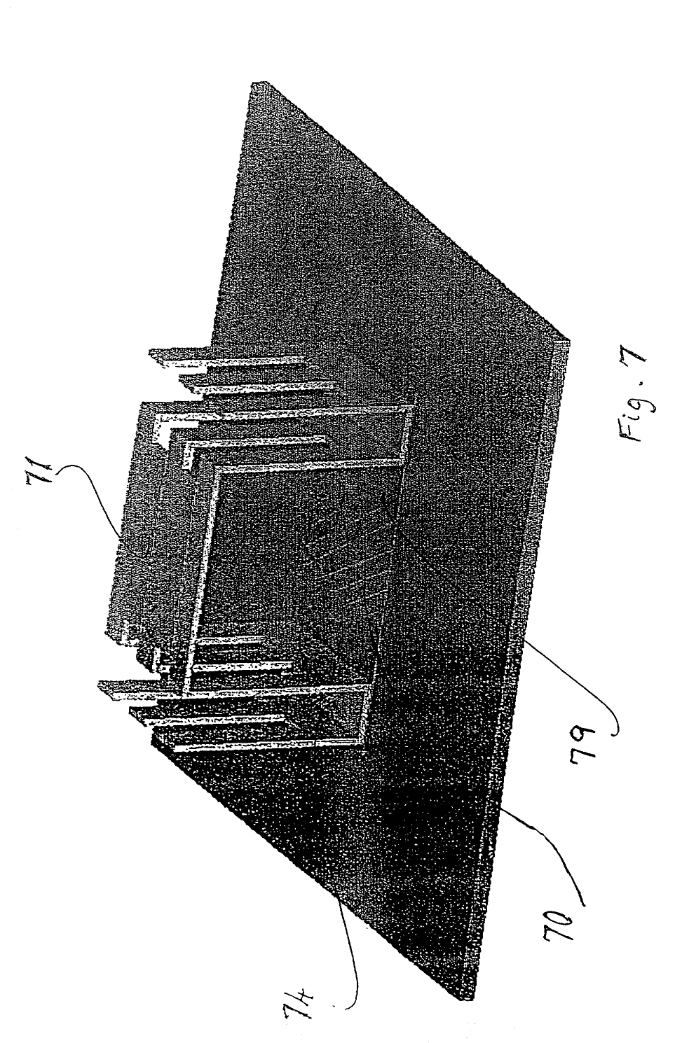

In use, the heat sink of the invention would be installed generally as shown in FIG. 7. As shown, a folded and slotted fin heat sink body 71 is surface mounted over a device 70, upon copper seating pads 79. The solderable elements and solder paste used for mounting are not shown in the figure but are present beneath the surface 74 for surface mounting the heat sink 71 upon the pads 79.

The invention is useful in the electronics field in obviating the need to use relatively expensive cooling components made from coated metals and alloys in surface mounting of heat sinks in functional proximity to electronic devices and packages. Improvements in heat sinks such as offered herein permit less expense to be incurred in board design. Furthermore, where a heat sink is made from copper coated with tin or an alloy thereof, apart from the relatively high cost thereof as compared with an aluminum heat sink, it has several limitations. Tinned-copper has poorer emissivity than anodized/painted aluminum, and cannot be treated to take pigments to improve its properties

A heat sink assembly made essentially of aluminum is of lighter weight than one made from coated copper or copper alloys, and thus offers advantages in the usual automatic assembly process that typically uses “pick and place” devices relying on aspirating means in the device manipulator.

Blackened aluminum exhibits increased heat absorption properties in comparison with reflective surfaces, and is particularly effective in the infra red ovens used to achieve the reflow soldering technique.

Aluminum heat sinks as described herein are readily recyclable by virtue of the mechanical assembly methods described herein and thus compares favorably with the tin coated copper plate heat sinks currently soldered in a surface mounted application.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A composite heat sink device for surface mounting to a circuit board, said device comprising:
a heat sink body consisting essentially of aluminum, said body comprising at least one mounting land with a substantially planar surface, and
a thermally conductive solderable element mechanically fixed to each said mounting land, each said element having a first planar surface which is contiguous with at least one said planar surface of said heat sink body and an opposed second planar surface for soldering to said circuit board.

2. A composite heat sink device as in claim 1 wherein said heat sink body has two of said lands, said substantially planar surfaces being coplanar.

3. A composite heat sink device as in claim 2 wherein said body comprises a heat dissipating fin upstanding from each of said lands, and a bight upstanding from said lands between said fins.

4. A composite heat sink device as in claim 3 wherein said bight has a planar section which is parallel to said lands and intended to be arranged over an electronic device on said circuit board.

5. A composite heat sink device as in claim 1 wherein said heat sink body is formed from a sheet of aluminum.

6. A composite heat sink device as in claim 5 wherein said heat sink body is formed from a sheet of anodized aluminum.

7. A composite heat sink device as in claim 6 wherein said anodized aluminum is blackened.

8. A composite heat sink device as in claim 1 wherein said heat sink body is extruded.

9. A composite heat sink device as in claim 1 wherein said element is mechanically fixed to said land by providing at least one projection on said land, providing at least one socket in each said element, and inserting each said projection into a respective at least one socket in an interference fit.

10. A composite heat sink device as in claim 9 wherein the element is swaged onto the land.
